(19) United States
(12) Patent Application Publication
(10) Pub. No.: US 2026/0016760 A1
(43) Pub. Date: Jan. 15, 2026

(54) IMAGE PROCESSING APPARATUS, INSPECTION APPARATUS, IMAGE PROCESSING METHOD, AND NON-TRANSITORY COMPUTER READABLE MEDIUM

(71) Applicant: Lasertec Corporation, Yokohama (JP)

(72) Inventors: Moeko KAWASAKI, Yokohama-shi (JP); Yoshihiro KATO, Yokohama-shi (JP)

(21) Appl. No.: 19/265,412

(22) Filed: Jul. 10, 2025

(30) Foreign Application Priority Data
Jul. 10, 2024 (JP) 2024-111181

(51) Int. Cl. G03F 7/00

(52) U.S. Cl. CPC G03F 7/70625; G03F 7/7065; G03F 7/706833; G03F 7/706849

(57) ABSTRACT

An image reading unit reads image data obtained by imaging a sample in which a plurality of regions is disposed including a pattern formed based on identical design information. An evaluation value acquisition unit acquires, from among sampling images at a plurality of sampling points set for each of the plurality of regions, an evaluation value based on luminance of pixels for a plurality of sampling images at the same sampling point of the plurality of regions. A reference evaluation value acquisition unit acquires a reference evaluation value relative to the evaluation value for a plurality of sampling images at the same sampling point in the plurality of regions. An equalized evaluation value acquisition unit acquires an equalized evaluation value indicating a degree of deviation of the evaluation value from the reference evaluation value, for each of the sampling images of the plurality of regions.

### INCORPORATION BY REFERENCE

This application is based upon and claims the benefit of priority from Japanese patent application No. 2024-111181, filed on Jul. 10, 2024, the disclosure of which is incorporated herein in its entirety by reference for all purposes.

### BACKGROUND

The present disclosure relates to an image processing apparatus, an inspection apparatus, an image processing method, and a non-transitory computer readable medium.

For example, in order to detect defects in a sample such as a photomask, a technique is widely used to inspect the sample by using an image captured by irradiating the sample with light (Japanese Unexamined Patent Application Publication No. 2017-187547).

A plurality of chip patterns based on the same design information, or so-called dies, may be arrayed on a photomask. When the plurality of dies is formed in this way, pattern dimensions of the same portion of the plurality of dies, so-called critical dimensions (CDs), are preferably identical. However, variations are known to occur in the CDs due to errors caused by the manufacturing process.

### SUMMARY

As described above, when variations in the CDs increase and deviate from a prescribed dimensional range, so-called CD defects occur. In recent years, there has been a demand for performing inspection of CD defects based on an image of the sample.

If it is possible to inspect CD defects based on the image, it is possible to detect CD defects in an apparatus that inspects other defects based on the image. In this case, a single apparatus can perform a plurality of types of inspection, and a reduction in inspection cost can be expected.

An image processing apparatus according to the present disclosure includes: one or more processors configured to execute instructions stored in a memory, the instructions causing the processors to perform: reading image data obtained by imaging a sample in which a plurality of regions are disposed, each region including a pattern formed based on identical design information; acquiring, from sampling images at a plurality of sampling points set for each of the plurality of regions, an evaluation value based on pixel luminance for a plurality of sampling images at the same sampling point across the plurality of regions; acquiring a reference evaluation value corresponding to the evaluation value for the plurality of sampling images at the same sampling point across the plurality of regions; and acquiring an equalized evaluation value indicating a degree of deviation of the acquired evaluation value from the reference evaluation value, for each of the sampling images of the plurality of regions.

An inspection apparatus according to the present disclosure includes the above image processing apparatus, in which the processors are further configured to detect a defect in a pattern of each of the sampling images of the plurality of regions based on the equalized evaluation value.

An inspection apparatus according to the present disclosure includes the above image processing apparatus, in which the processors are further configured to detect a defect smaller than a width of the pattern based on a difference between the evaluation value of the sampling images and an evaluation value of sampling images in a reference image.

An image processing method according to the present disclosure includes: reading image data obtained by imaging a sample in which a plurality of regions are disposed including a pattern formed based on identical design information; acquiring, from among sampling images at a plurality of sampling points set for each of the plurality of regions, an evaluation value based on luminance of pixels for a plurality of sampling images at the same sampling point across the plurality of regions; acquiring a reference evaluation value relative to the evaluation value for a plurality of sampling images at the same sampling point across the plurality of regions; and acquiring an equalized evaluation value indicating a degree of deviation of the acquired evaluation value from the reference evaluation value, for each of the sampling images of the plurality of regions.

A non-transitory computer readable medium storing a program according to the present disclosure for causing a computer to execute: processing of reading image data obtained by imaging a sample in which a plurality of regions are disposed including a pattern formed based on identical design information; processing of acquiring, from among sampling images at a plurality of sampling points set for each of the plurality of regions, an evaluation value based on luminance of pixels for a plurality of sampling images at the same sampling point across the plurality of regions; processing of acquiring a reference evaluation value relative to the evaluation value for the plurality of sampling images at the same sampling point across the plurality of regions; and processing of acquiring an equalized evaluation value indicating a degree of deviation of the acquired evaluation value from the reference evaluation value, for each of the sampling images of the plurality of regions.

According to the present disclosure, it is possible to evaluate the presence or absence of a defect in a pattern formed on a sample based on an image.

The above and other objects, features and advantages of the present disclosure will become more fully understood from the detailed description given hereinbelow and the accompanying drawings.

### BRIEF DESCRIPTION OF DRAWINGS

FIG. 1 is a diagram showing a configuration example of an inspection system according to a first embodiment;

FIG. 2 is a top view of a sample;

FIG. 3 is a top view showing an arrangement of sampling points on one die;

FIG. 4 is a diagram schematically showing a configuration example of an image processing apparatus according to the first embodiment;

FIG. 5 is a flowchart showing an operation of the image processing apparatus according to the first embodiment;

FIG. 6 is a diagram showing an example of a pattern and an edge region of each die;

FIG. 7 is a diagram schematically showing a configuration of an image processing apparatus according to a second embodiment;

FIG. 8 is a diagram showing a mapping example of equalized evaluation values;

FIG. 9 is a block diagram schematically showing a configuration of an inspection apparatus according to a third embodiment; and

FIG. 10 is a diagram showing a configuration example of a computer for realizing the image processing apparatus and the inspection apparatus.

### DESCRIPTION OF EMBODIMENTS

Hereinafter, specific configurations of embodiments will be described with reference to the drawings. The following description presents preferable embodiments of the present disclosure, and the scope of the present disclosure is not limited to the embodiments described below. In the following description, elements denoted by the same reference sign represent essentially the same content.

### First Embodiment

An image processing apparatus according to a first embodiment will be described. The image processing apparatus according to the present embodiment is incorporated into an optical apparatus such as an inspection apparatus used to inspect a sample such as a photomask used in a semiconductor manufacturing process.

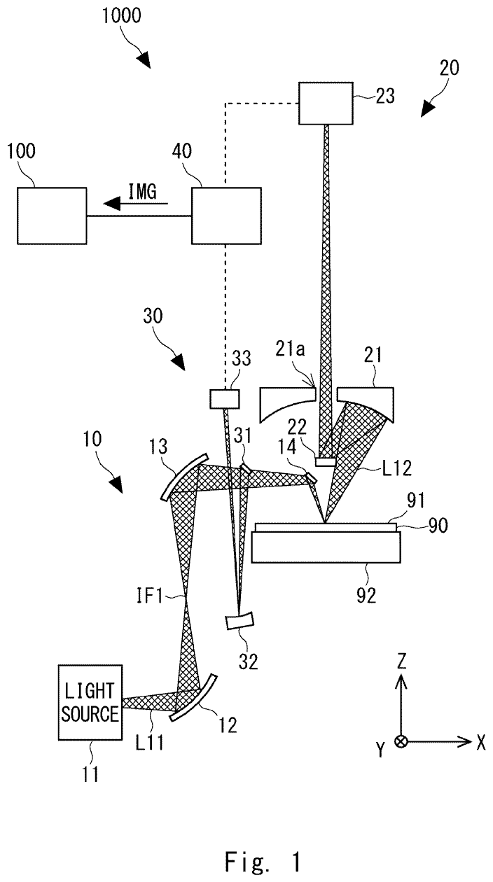

First, the optical apparatus according to the first embodiment will be described. FIG. 1 is a diagram schematically showing a configuration of an optical system of the optical apparatus according to the first embodiment. As shown in FIG. 1, an optical apparatus 1000 according to the present embodiment is configured as an apparatus that inspects an inspection target by irradiating a sample 90 being the inspection target with illumination light and detecting reflected light. The sample 90 being the inspection target of the optical apparatus 1000 is, for example, an extreme ultraviolet (EUV) mask, and the optical apparatus 1000 irradiates the sample 90 with EUV light. The sample 90 is not limited to the EUV mask, but may be various types of materials on which fine patterns are formed, such as various types of photomasks designed for light with a longer wavelength than EUV light or semiconductor wafers on which circuit patterns are formed.

The optical apparatus 1000 includes an illumination optical system 10, a detection optical system 20, a monitor section 30, and a processing unit 40. The illumination optical system 10 includes a light source 11, a spheroidal mirror 12, a spheroidal mirror 13, and a dropping mirror 14. The detection optical system 20 includes a concave mirror with hole 21, a convex mirror 22, and a first detector 23. The concave mirror with hole 21 and the convex mirror 22 constitute a Schwarzschild magnification optical system. The monitor section 30 includes a cut mirror 31, a concave mirror 32, and a second detector 33.

The light source 11 emits, as illumination light L11, EUV light with an exposure wavelength of 13.5 nm which is the same as that of the sample 90 being an EUV mask. The illumination light L11 is not limited to EUV light, but may be light with another wavelength in accordance with the sample 90. The illumination light L11 emitted from the light source 11 is reflected by the spheroidal mirror 12. The illumination light L11 reflected by the spheroidal mirror 12 is focused to a focusing point IF1 at a position conjugate to a top surface 91 of the sample 90, and is subsequently incident on a reflecting mirror such as the spheroidal mirror 13 while spreading out.

The illumination light L11 incident on the spheroidal mirror 13 is reflected by the spheroidal mirror 13. The illumination light L11 reflected by the spheroidal mirror 13 is incident on the dropping mirror 14 while being focused. That is, the spheroidal mirror 13 causes the illumination light L11 to be incident on the dropping mirror 14 as converged light. The dropping mirror 14 is disposed directly above the sample 90. The illumination light L11 incident on the dropping mirror 14 is reflected to be incident on the sample 90. In other words, the illumination light L11 is reflected by the dropping mirror 14 and is incident on the sample 90.

The spheroidal mirror 13 is designed and disposed to focus the illumination light L11 on the sample 90. The illumination optical system 10 is disposed so that an image of the light source 11 is formed on the top surface 91 of the sample 90 when the illumination light L11 illuminates the sample 90. Thus, the illumination optical system 10 is critical illumination. In this way, the illumination optical system 10 illuminates the inspection target using critical illumination with the illumination light L11 generated by the light source 11.

The sample 90 is disposed on a stage 92. Here, a plane parallel to the top surface 91 of the sample 90 is an XY-plane, and a direction normal to the XY-plane is a Z-direction. The illumination light L11 is incident on the sample 90 from a direction inclined with respect to the Z-direction. That is, the illumination light L11 is incident at an oblique angle and illuminates the sample 90.

The stage 92 is an XYZ-drive stage. By moving the stage 92 in an XY-direction, it is possible to illuminate a desired region of the sample 90. Furthermore, it is possible to perform focus adjustment by moving the stage 92 in the Z-direction.

The illumination light L11 from the light source 11 illuminates an inspection region of the sample 90. The inspection region illuminated by the illumination light L11 is, for example, 0.5 mm square. Reflected light L12 incident from a direction inclined with respect to the Z-direction and reflected by the sample 90 is incident on the concave mirror with hole 21. A hole 21a is provided in a center of the concave mirror with hole 21.

The reflected light L12 reflected by the concave mirror with hole 21 is incident on the convex mirror 22. The convex mirror 22 reflects the reflected light L12 incident from the concave mirror with hole 21 toward the hole 21a in the concave mirror with hole 21. The reflected light L12 passing through the hole 21a is detected by the first detector 23. The first detector 23 is a detector including a time delay integration (TDI) sensor, and acquires image data of the sample 90 being the inspection target. The first detector 23 includes a plurality of imaging elements linearly arranged in one direction. Linear image data captured by the plurality of imaging elements linearly arranged is referred to as one-dimensional image data or one frame. The first detector 23 acquires a plurality of pieces of one-dimensional image data by scanning in a direction orthogonal to the one direction. The imaging element is, for example, a charge coupled device (CCD). Note that the imaging element is not limited to the CCD.

In this way, the detection optical system 20 focuses the reflected light L12 from the sample 90 illuminated by the illumination light L11, detects the focused reflected light L12 via the first detector 23, and acquires the image data of the sample 90. The image data is, for example, one-dimensional image data.

The reflected light L12 includes information such a defect or the like in patterns or the like formed on the sample 90. In the present configuration, the reflected light L12 being positive reflected light of the illumination light L11 incident on the sample 90 from the direction inclined with respect to the Z-direction is detected by the detection optical system 20. When a defect is present in the sample 90, the defect is observed as a dark image. This observation method is referred to as bright-field observation. The plurality of pieces of one-dimensional image data of the sample 90 acquired by the first detector 23 are output to the processing unit 40 and processed into two-dimensional image data.

As shown in FIG. 1, the cut mirror 31 of the monitor section 30 is disposed between the spheroidal mirror 13 and the dropping mirror 14, and extracts a portion of the illumination light L11 between the spheroidal mirror 13 and the dropping mirror 14. The cut mirror 31 reflects the illumination light L11 so as to slightly cut out a portion of a beam thereof. The portion of the beam is, for example, a top portion of the beam.

In the cross-sectional area of a cross section orthogonal to an optical axis of the illumination light L11 at a position where the cut mirror 31 is disposed, a cross-sectional area of the portion reflected by the cut mirror 31 is smaller than that of the illumination light L11 other than the portion.

For example, if the cross-sectional area of the cross section orthogonal to the optical axis of the illumination light L11 at the position where the cut mirror 31 is disposed is 100, the cross-sectional area of the portion is approximately 1. For the illumination light L11 extracted from the light source 11, an extraction angle in a direction orthogonal to the optical axis is, for example, ±7°. The extraction angle used for the illumination light L11 with respect to the sample 90 is, for example, in a range of ±6°. In order to use the portion of the illumination light L11 for the monitor section 30, the upper portion of the beam of the illumination light L11 is slightly extracted by the cut mirror 31 in, for example, a range of 1°. Even when the upper portion of the beam is slightly extracted in this way, the amount of the illumination light L11 incident on the sample 90 does not decrease that much. Thus, it is possible to suppress a reduction in accuracy for the inspection target.

The cut mirror 31 is, for example, disposed at a position close to a pupil in the illumination optical system 10. By extracting the illumination light L11 via the cut mirror 31 at the position close to the pupil in the illumination optical system 10, it is possible to obtain a satisfactory correlation between the image data acquired by the first detector 23 and image data acquired by the second detector 33. Even when a numerical aperture (NA) for the first detector 23 is different from a NA for the second detector 33, and point spread functions (PSFs) thereof are different from each other, a difference in the NA does not affect the present embodiment because a plasma size is sufficiently larger than a PSF size.

The illumination light L11 reflected by the cut mirror 31 is incident on the concave mirror 32 while spreading out after being focused to a focusing point.

The concave mirror 32 and a plurality of mirrors (not shown) spread out the beam of the illumination light L11 extracted by the cut mirror 31. With this, it is possible to magnify the image data acquired by the second detector 33. For example, a magnification can be set to 500 times by using the plurality of mirrors.

In the present embodiment, a magnification of image data of a luminance distribution acquired by the monitor section 30 is set to the same magnification as that of the image data of the inspection target acquired by the detection optical system 20. Note that the magnification of the image data of the luminance distribution acquired by the monitor section 30 may be set to be lower than that of the image data of the inspection target acquired by the detection optical system 20. A solid angle required for the extraction is the square of the magnification ratio. For example, when the magnification of the first detector 23 is set to 20 times and the magnification of the second detector 33 is set to 2 times, the solid angle required for the extraction by the cut mirror 31 is 1/100 of the solid angle for the extraction from the light source 11. When converting in terms of NA, the solid angle required for the extraction by the cut mirror 31 is 1/10 of the solid angle for the extraction from the light source 11.

The illumination light L11 incident on the concave mirror 32 and reflected by the concave mirror 32 is detected by the second detector 33. The second detector 33 includes a TDI sensor, and acquires the image data of the luminance distribution of the illumination light L11. The second detector 33 includes a plurality of imaging elements linearly arranged in one direction. Linear image data captured by the plurality of imaging elements linearly arranged being referred to as one-dimensional image data or one frame is similarly to the first detector 23. The second detector 33 acquires a plurality of pieces of one-dimensional image data by scanning in a direction orthogonal to the one direction. The one-dimensional image data acquired by the second detector 33 shows a power fluctuation and the luminance distribution of the illumination light L11. The imaging element is, for example, a CCD. Note that the imaging element is not limited to the CCD.

For example, the optical system of the monitor section 30 may be disposed so that an image of the light source 11 of the illumination light L11 is formed on the second detector 33. In this case, the first detector 23 and the second detector 33 are conjugate. In this way, the monitor section 30 can acquire image data capable of identifying the power fluctuation, the luminance distribution, and the like of the illumination light L11 (may hereinafter be referred to as “image data of the power fluctuation and the luminance distribution”, “monitor image”, or the like) detected by illuminating the second detector 33 with critical illumination by using a portion of the illumination light L11. Thus, it is possible to accurately correct the luminance distribution and the power fluctuation.

The monitor section 30 outputs the image data of the power fluctuation and the luminance distribution of the acquired illumination light L11 to the processing unit 40.

The processing unit 40 is wiredly or wirelessly connected to the detection optical system 20 and the monitor section 30. The processing unit 40 receives the image data of the inspection target from the first detector 23 in the detection optical system 20. The processing unit 40 receives the image data of the power fluctuation and the luminance distribution of the illumination light L11 from the second detector 33 in the monitor section 30.

The processing unit 40 may perform correction of the image data of the sample 90 acquired by the detection optical system 20, based on the image data of the power fluctuation and the luminance distribution acquired by the monitor section 30. The processing unit 40 may, for example, correct the luminance distribution of pixels included in the image data through shading correction, in order to compensate for an influence of the luminance distribution of the critical illumination.

An overview of the shading correction will be described. A case is assumed in which a luminance profile of pixels in a certain direction has an upward convex shape in original image data generated based on a detection result from the first detector 23. In this case, the processing unit 40 performs the shading correction by applying gain with a profile having an upward convex shape to the luminance profile of the pixels. With this, the shading-corrected profile becomes flat-shaped. By making the luminance profile of the pixels flat, it is possible to, for example, more accurately execute defect inspection on an object based on a difference between the luminance of a certain pixel and that of surrounding pixels. The profile of the gain used for the shading correction may be any shape as long as the luminance profile of the pixels after the shading correction is a freely-selected shape (for example, more flat-shaped).

When critical illumination is used in the above-described optical apparatus 1000, the luminance distribution in the first detector 23 is greatly affected by a state of the light source (bright spot). This is because, for example, when the light source (bright spot) moves with a component in a direction parallel to a surface that is a normal direction of the optical axis, a position (apex position) at which the luminance profile in the first detector 23 has an upward convex shape fluctuates. In Japanese Patent No. 6249513, shading correction is proposed that takes into account fluctuation in the luminance distribution at the first detector 23 due to the state of the light source, and the processing unit 40 may perform shading correction that takes into account fluctuation in the luminance distribution at the first detector 23 by using a similar method.

When performing shading correction similar to that of Japanese Patent No. 6249513, the processing unit 40 determines how to apply predetermined gain to the luminance profile acquired by the first detector 23 based on the luminance profile acquired by the second detector 33. As an example, the processing unit 40 performs shading correction for the first detector 23 using gain obtained by moving the predetermined gain by +x1 in an X-axis direction, based on a result of determining that an apex position of the luminance profile acquired by the second detector 33 has moved by +x1 in the X-axis direction relative to an apex position of a reference luminance profile. Alternatively, as another example, the processing unit 40 performs shading correction for the first detector 23 using gain obtained by reducing the predetermined gain by −ΔI, based on a result of determining that an intensity at the apex position of the luminance profile acquired by the second detector 33 is greater than an intensity at the apex position of the reference luminance profile by ΔI. Note that in the present description, the apex position of the luminance profile of the second detector 33 is a comparison target, but is not limited thereto and any point may be used as the comparison target. The movement of the predetermined gain in the X-axis direction, an intensity direction, or the like may be applied to the entire predetermined gain, or to a portion of the predetermined gain, such as a field of view position (position on the X-axis) where fluctuation is particularly large. In this way, by performing shading correction similar to that of Japanese Patent No. 6249513, it is possible to correct the luminance distribution of the critical illumination light depending on changes, even when changes occur in the luminance distribution over time.

The processing unit 40 outputs, to an image processing apparatus 100, image data IMG including image data corrected in this way.

The image data IMG generated by the optical apparatus 1000 based on an imaging result of the sample 90 will be described. In the present embodiment, the sample 90 consists of a plurality of dies on which patterns are formed based on identical design information arrayed on a plane, like a typical photomask, a semiconductor wafer in a semi-finished state, or the like. The optical apparatus 1000 performs imaging of one or more of the same locations on each die in order to inspect manufacturing variations, defects, or the like in a surface of the sample 90 by using die-to-die (D2D) or die-to-database (DDB). The image data IMG is generated as a dataset of captured images. This will be described in detail below.

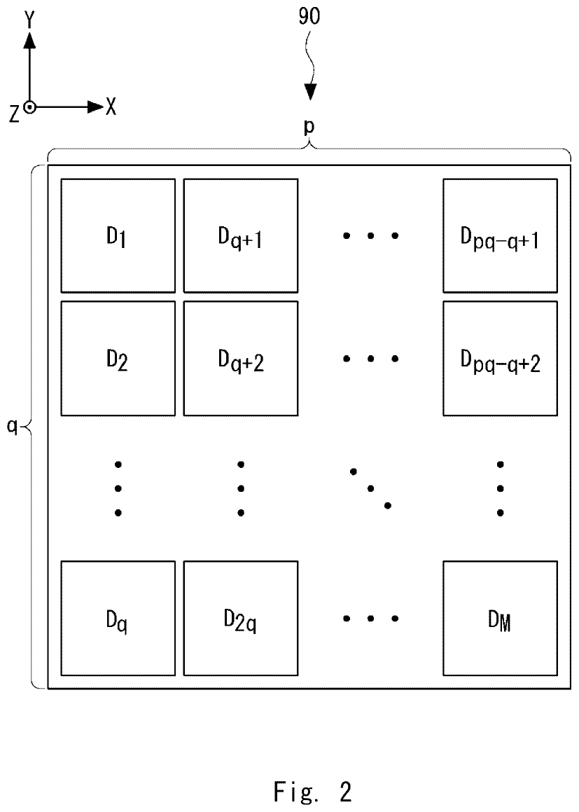

FIG. 2 is a top view of the sample 90. In the top view, a horizontal direction of the page is an X-axis direction and the vertical direction of the page is a Y-axis direction. On the sample 90, a plurality of die patterns formed based on the identical design information are arrayed in the X-axis direction and the Y-axis direction. On the sample 90, p*q=M dies D₁ to D_{M} are arrayed, where column p is in the X-axis direction and row q is in the Y-axis direction. Here, p and q are integers of 2 or higher. However, a die arrangement in FIG. 2 is merely an example, and a different number of dies may be arranged in different positions on the sample 90.

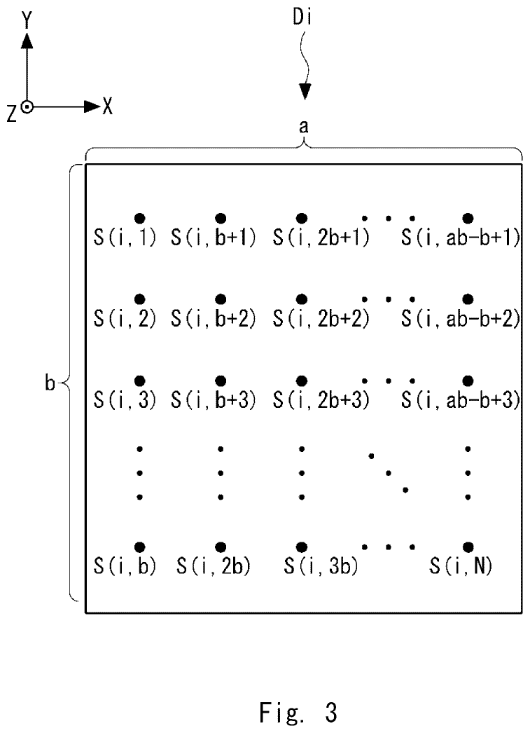

On each of the M dies, a plurality of sampling points are arrayed in the X-axis direction and the Y-axis direction. FIG. 3 is a top view showing an arrangement of the sampling points on one die. Here, when i is an integer of 1 or higher and M or lower, an i-th die is denoted as die Dᵢ. On the die Dᵢ, a*b=N sampling points S(i,1) to S(i,N) are arrayed, where column a is in the X-axis direction and row b is in the Y-axis direction. Here, a and b are integers of 2 or higher. In other words, since each of the M dies Dᵢ to D_{M} includes N sampling points, M*N sampling points are disposed on the sample 90. However, a sampling point arrangement in FIG. 3 is merely an example, and a different number of sampling points may be arranged in different positions on each die.

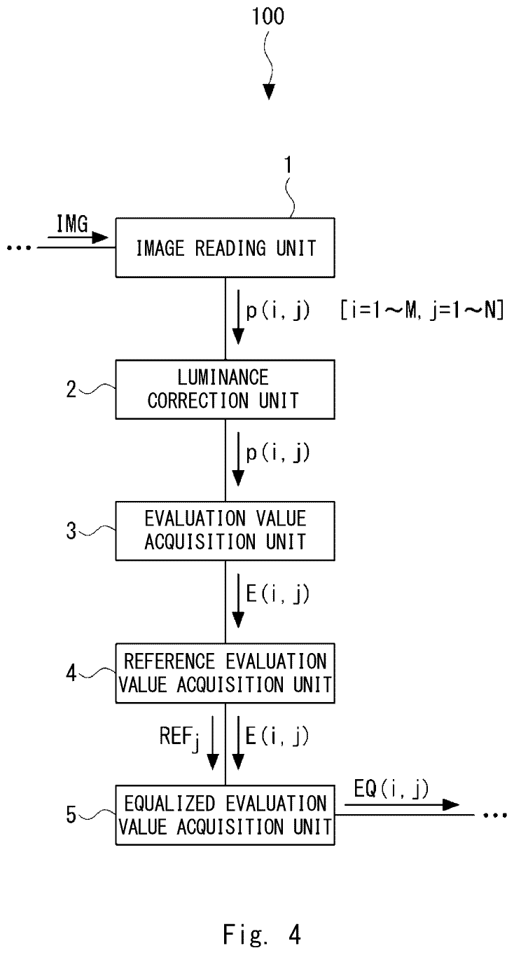

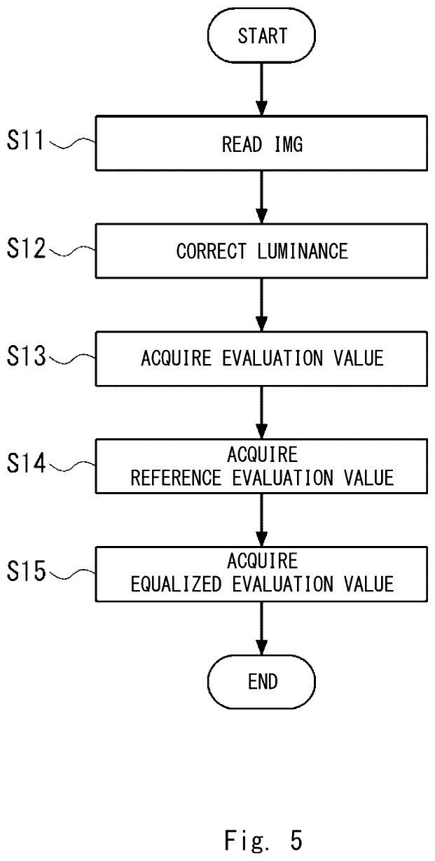

Next, a configuration and an operation of the image processing apparatus 100 will be described. FIG. 4 is a diagram schematically showing a configuration example of the image processing apparatus according to the first embodiment. FIG. 5 is a flowchart showing the operation of the image processing apparatus according to the first embodiment. The image processing apparatus 100 includes an image reading unit 1, a luminance correction unit 2, an evaluation value acquisition unit 3, a reference evaluation value acquisition unit 4, and an equalized evaluation value acquisition unit 5.

The image reading unit 1 reads the image data IMG of the sample 90 captured by the optical apparatus 1000 (step S11 in FIG. 5). Note that the image reading unit 1 may read the image data IMG from the optical apparatus 1000, or may read the image data IMG stored in a freely-selected storage apparatus.

The luminance correction unit 2 corrects variations in luminance of M images at the sampling points in the same position of the M dies (step S12 in FIG. 5). Hereafter, an image at a j-th sampling point S(i,j) of the i-th die Dᵢ is referred to as a sampling image p(i,j). In other words, the luminance correction unit 2 normalizes luminance of pixels included in a j-th sampling image p(i,j) of first to M-th dies Dᵢ to D_{M} to a predetermined range. The luminance correction unit 2 performs this correction processing for each of first through N-th sampling images.

Note that when the sample 90 is imaged using the critical illumination in the optical apparatus 1000, in-surface variations in the luminance of the pixels included in the sampling images may be corrected through shading correction also in luminance correction processing by the luminance correction unit 2, in order to compensate for the influence of the luminance distribution of the critical illumination. Similarly, in illumination other than critical illumination, in-surface variations in the luminance of the pixels included in the sampling images may be corrected in accordance with the luminance distribution of the illumination light. The in-surface variations in the luminance of the pixels included in the sampling images may be corrected taking into account temporal fluctuation in the luminance distribution of the critical illumination due to differences in imaging timing, by using various methods such as the method in Japanese Patent No. 6249513.

After the luminance correction processing, the evaluation value acquisition unit 3 acquires, as an evaluation value E(i,j) of the sampling image p(i,j), an average value of luminance of pixels included in an edge region R defined as a region where edges of the pattern are present in the sampling image p(i,j) (step S13 in FIG. 5). The edge region R may be specified in advance for each sampling point, based on the die design information. Note that when the sampling image p(i,j) is a single pixel, the evaluation value E(i,j) may be a luminance value of the pixel in the sampling image p(i,j).

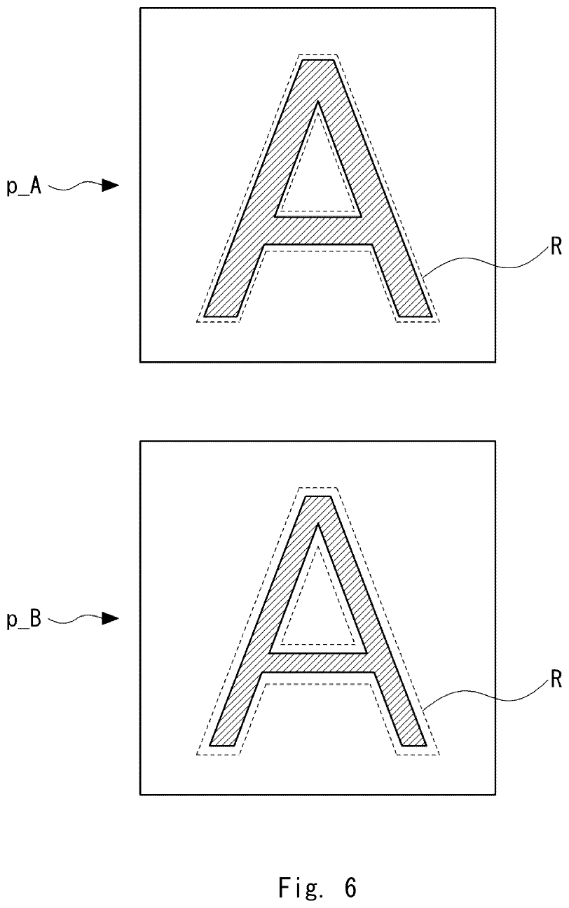

FIG. 6 is a diagram showing an example of the pattern and the edge region of each die. In this example, a pattern of the letter A is formed in the sampling image p(i,j), and luminance of the letter portion of A is high and luminance of the non-letter portion is low. The edge region R shown as a dotted line is set so as to encompass an edge portion of A. If dimensions of the A pattern with high luminance fluctuates due to CD variation, the average value of the pixels in the edge region R, that is, the evaluation value also varies.

In FIG. 6, as an example, a sampling image p_A in a case in which lines constituting the pattern are comparatively thick and a sampling image p_B in a case in which lines constituting the pattern are comparatively thin are displayed. In this case, an evaluation value of the sampling image p_A is greater than that of the sampling image p_B because more pixels with higher luminance are present in an edge region R of the sampling image p_A than in an edge region R of the sampling image p_B.

The evaluation value acquisition unit 3 performs evaluation value acquisition processing for all sampling images of all dies. In other words, the evaluation value acquisition unit 3 performs the acquisition of the evaluation value E(i,j) of the sampling image p(i,j) in a range of 1≤i≤M and 1≤j≤N.

The reference evaluation value acquisition unit 4 acquires a reference evaluation value REFⱼ being a comparison target for evaluating evaluation values E(1,j) to E(M,j) of j-th sampling images p(1,j) to p(M,j) of the first to M-th dies D₁ to D_{M} (step S14 in FIG. 5).

Here, an example is described in which the reference evaluation value acquisition unit 4 acquires the reference evaluation value REFⱼ based on the evaluation value of each sampling image acquired by the evaluation value acquisition unit 3. For example, the reference evaluation value acquisition unit 4 acquires, as the reference evaluation value REFⱼ of the j-th sampling images, an average value of the evaluation values E(1,j) to E(M,j) of the j-th sampling images p(1,j) to p(M,j) of the first to M-th dies Dᵢ to D_{M}.

$${REF}_{j} = {{\sum }_{i = 1}}^{M} E ( i , j ) \qquad [ Mathematical formula 1 ]$$

The reference evaluation value acquisition unit 4 may acquire a value different from the above-described average value as the reference evaluation value REFⱼ, as long as the reference evaluation value acquisition unit 4 can acquire a value being a reference for the evaluation values E(1,j) to E(M,j) as the reference evaluation value REFⱼ. For example, the reference evaluation value acquisition unit 4 may acquire a value determined in advance based on the design information of the sample 90 as the reference evaluation value REFⱼ. As an example, the reference evaluation value acquisition unit 4 may acquire, as the reference evaluation value REFⱼ, a value obtained from an image corresponding to the j-th sampling points of the dies among images generated from the design information of the sample 90. When used in combination with microdefect inspection through DDB to be described below, it is convenient to acquire the value obtained based on the design information of the sample 90 in this way as the reference evaluation value REFⱼ.

The equalized evaluation value acquisition unit 5 acquires an equalized evaluation value EQ(i,j) of the j-th sampling image p(i,j) of the i-th die Dᵢ based on the following formula (step S15 in FIG. 5).

$$EQ ( i , j ) [ \% ] = \frac{100 ( E ( i , j ) - {REF}_{j} )}{{REF}_{j}} \qquad [ Mathematical formula 2 ]$$

That is, the equalized evaluation value EQ (i,j) can be understood to be an index indicating to which degree the j-th sampling image p(i,j) of the i-th die Dᵢ deviates from the reference evaluation value REFⱼ, that is, the average value of the j-th sampling images p(1,j) to p(M,j) of the first to M-th dies Dᵢ to D_{M}.

In this way, according to the image processing apparatus 100, it is possible obtain an equalized evaluation value indicating to which degree a pattern at one sampling point set for each die deviates from an average pattern at the same sampling point on all dies, when a plurality of dies with the same pattern are formed on the sample 90.

With this, according to the image processing apparatus 100, it is possible to evaluate CD variations in the patterns formed on the sample 90. By using the equalized evaluation value, the image processing apparatus 100 can detect not only CD defects but also other defects, such as pattern contamination.

It is possible to easily integrate the acquisition of the evaluation values in the image processing apparatus 100 with other image processing apparatuses that perform predetermined image processing on an image of the sample 90. Therefore, it is possible to realize a multi-functional image processing apparatus that performs the acquisition of the equalized evaluation value and other image processing. By incorporating the configuration and functions of the image processing apparatus according to the present embodiment in an existing image processing apparatus that performs other image processing based on the image of the sample 90, it is possible to easily realize an image processing apparatus capable of performing the acquisition of the equalized evaluation value and the other image processing.

### Second Embodiment

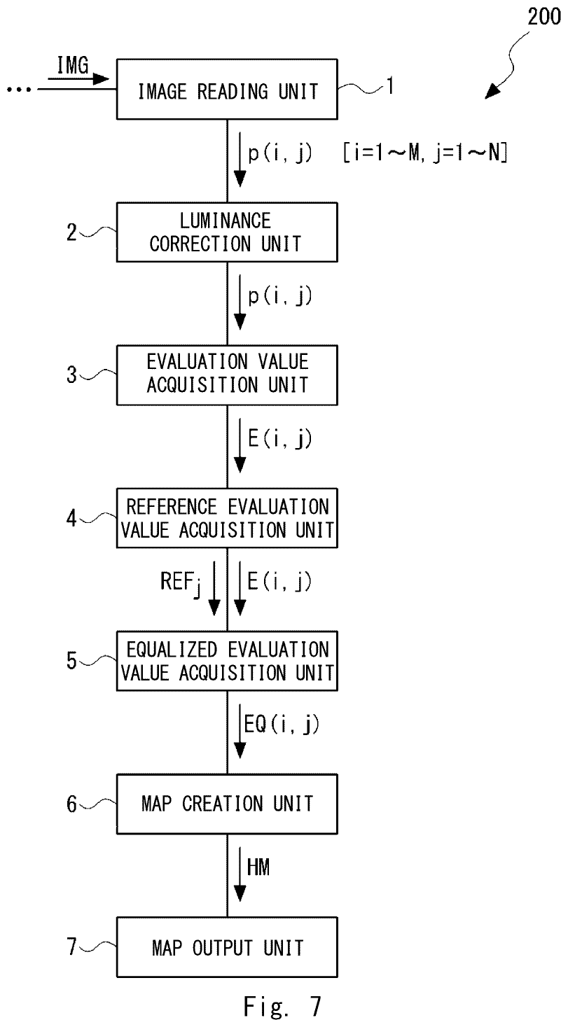

An image processing apparatus according to a second embodiment will be described. An image processing apparatus according to the present embodiment is configured to visualize a distribution of the equalized evaluation value in the sample 90. FIG. 7 is a diagram schematically showing a configuration of the image processing apparatus according to the second embodiment. Comparing an image processing apparatus 200 according to the second embodiment with the image processing apparatus 100 according to the first embodiment, the image processing apparatus 200 further includes a map creation unit 6 and a map output unit 7.

The map creation unit 6 creates a heat map HM that maps M*N equalized evaluation values acquired by the equalized evaluation value acquisition unit 5 for each of the N sampling points of the M dies onto a two-dimensional plane.

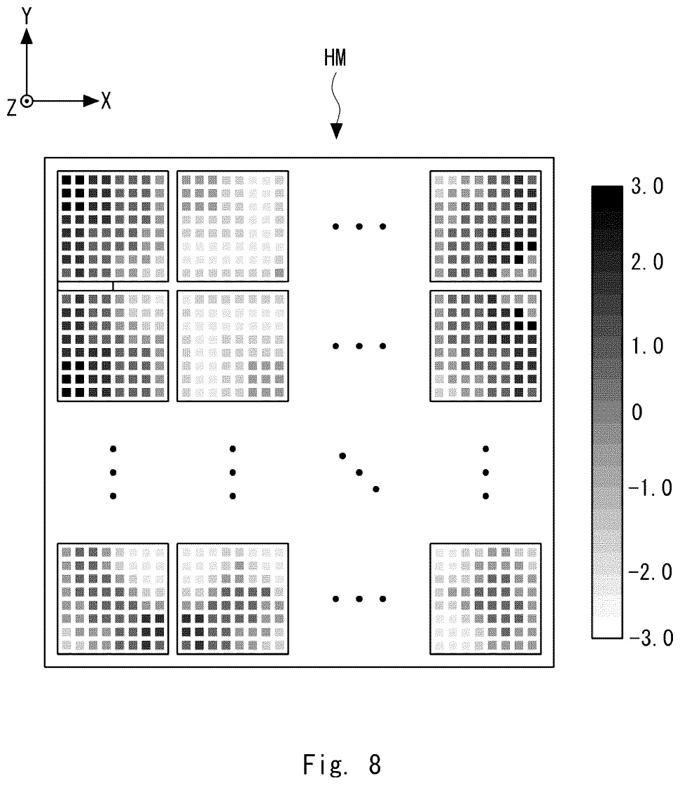

FIG. 8 is a diagram showing a mapping example of equalized evaluation values. As shown in FIG. 8, for example, the equalized evaluation values at the sampling points set for the sample can be displayed in grayscale. In this case, grayscale gradients may be set so that the darkest gradient corresponds to a maximum value on a +side, the lightest gradient to a maximum value on a-side, and an intermediate gradient to 0.

For example, mapping may be performed using different hues, so that a darker gradient is used as an absolute value of the equalized evaluation values increases, where red is used when the value is positive, blue is used when the value is negative, and the like.

The map output unit 7 provides a user the image processing apparatus with the heat map HM created by the map creation unit 6 as visible information. The map output unit 7 may be configured, for example, as a display apparatus such as a liquid-crystal monitor that displays the heat map HM to the user. The map output unit 7 may also be configured as a printing machine that visibly transfers the heat map HM onto a medium such as paper.

According to the image processing apparatus 200, the user can efficiently recognize CD variations in the patterns formed on the sample 90 by visibly displaying the CD variations in the patterns.

### Third Embodiment

An inspection apparatus according to a third embodiment will be described. The inspection apparatus according to the present embodiment is configured to determine whether the CDs of the patterns of each sampling image are within a prescribed range, based on the equalized evaluation values obtained by the image processing apparatus 100.

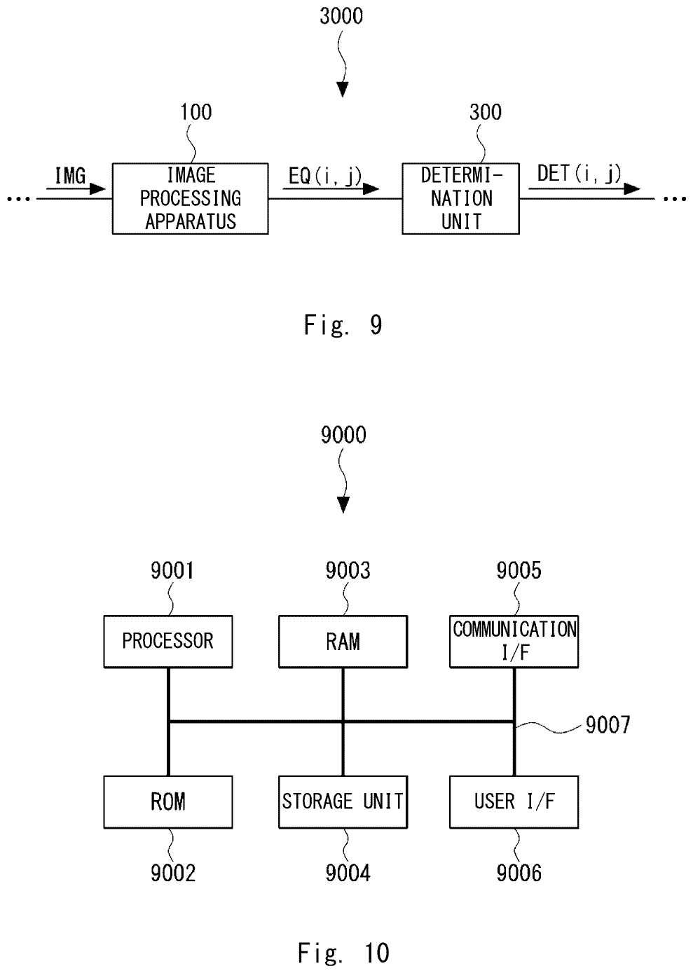

FIG. 9 is a block diagram schematically showing a configuration of the inspection apparatus according to the third embodiment. An inspection apparatus 3000 includes the image processing apparatus 100 and a determination unit 300.

The determination unit 300 compares the equalized evaluation values of each sampling image acquired by the image processing apparatus 100 with a determination reference range, and determines that a CD defect is present in the patterns of the sampling images for the compared equalized evaluation values when the equalized evaluation values of each sampling image deviate from the determination reference range. Such determination is referred to as determination based on a magnitude of an anomaly. The determination unit 300 outputs a determination result DET (i,j). In this way, the determination unit 300 can detect CD defects such as CD variations in the patterns.

The inspection apparatus 3000 is described above as detecting CD defects in the patterns of the sampling images, but this is merely an example. As described above, a single inspection apparatus can preferably inspect a plurality of types of defects. Therefore, the inspection apparatus 3000 may, for example, be configured to detect defects smaller than a pattern width (micro-defects) in the sample 90, based on the luminance of the pixels in the image of the sample 90.

Next, a defect detection method of detecting micro-defects in the inspection apparatus 3000 will be described. The determination unit 300 determines that a micro-defect is present at the sampling point S(i,j) of the die Dᵢ being the inspection target, when a difference between an evaluation value E (s,j) in the sampling image p(s,j) and the evaluation value E(i,j) in the sampling image p(i,j) at a j-th sampling point common to a die Ds being an inspection reference and the die Dᵢ being the inspection target falls outside the determination reference range. The determination unit 300 outputs the determination result DET(i, j). Here, the evaluation value E(s,j) may be referred to as an evaluation value of a sampling image in a reference image. Such a determination method for defects is generally referred to as micro-defect inspection using die-to-die (D2D).

The determination unit 300 may determine that a micro-defect is present at the sampling point S(i,j) of the die Dᵢ being the inspection target, when a difference between the evaluation value E(i,j) of the sampling image p(i,j) at the j-th sampling point of the die Dᵢ being the inspection target and an evaluation value acquired from a sampling image in an image generated from the design information of the sample 90 falls outside the determination reference range. Here, the evaluation value acquired from the sampling image based on the image generated from the design information of the sample 90 may be referred to as the evaluation value of the sampling image in the reference image. Such a determination method for defects is generally referred to as micro-defect inspection using die-to-database (DDB).

In the inspection apparatus 3000, a size of an image to be used as the sampling image, that is, the number of pixels to be included in the sampling image may be set for each type of defect being a determination target. For example, the number of pixels included in the sampling image used in the detection of micro-defects by the determination unit 300 may be less than the number of pixels included in the sampling image used in the detection of CD defects.

The number of pixels included in the sampling image used in the detection of micro-defects may be one. That is, by setting the sampling image p(i,j) as a single pixel and the evaluation value E(i,j) as a luminance value of the single pixel, micro-defects can be suitably detected.

According to the inspection apparatus 3000, it is possible to automatically and efficiently detect CD defects in the pattern of each sampling image of the sample 90.

According to the inspection apparatus 3000, the detection of CD defects and the detection of defects smaller than the pattern width in the sample 90 can also be performed by a single apparatus, and a reduction in inspection cost can be expected.

It is possible to easily integrate the CD defect inspection in the inspection apparatus 3000 with other inspection apparatuses that perform other types of pattern defect inspection based on the image of the sample 90. Therefore, it is possible to realize a multi-functional inspection apparatus that performs the CD defect inspection and other defect inspection. By installing the image processing apparatus and the determination unit according to the present embodiment in an existing inspection apparatus that performs other types of pattern defect inspection based on the image of the sample 90, it is possible to easily realize an inspection apparatus capable of performing CD defect inspection.

### OTHER EMBODIMENTS

The present disclosure has been described above with reference to the embodiments, but the present disclosure is not limited to the above-described embodiments. Various changes can be made to the configurations, contents, and the like of the present disclosure that can be understood by those skilled in the art within the scope of the present disclosure. The embodiments can be combined with the other embodiments as appropriate.

In the inspection apparatus according to the third embodiment, the heat map HM may be created and output by replacing the image processing apparatus 100 with the image processing apparatus 200.

In the inspection apparatus according to the third embodiment, the determination unit 300 is described as comparing the equalized evaluation values of each sampling image acquired by the image processing apparatus 100 with the determination reference range and determining that a CD defect is present in the patterns of the sampling images for the compared equalized evaluation values when the equalized evaluation values of each sampling image falls outside the determination reference range, but the determination unit 300 may determine that a CD defect is present by using another method.

For example, the determination unit 300 may determine, from among a predetermined plurality (referred to as prescribed number) of adjacent sampling images, that a CD defect is present in the pattern based on the number or ratio of sampling images for which the equalized evaluation value is outside of the determination reference range. As an example, the determination unit 300 may determine, from among a prescribed number of 3*3=9 adjacent sampling images, that a CD defect is present in a region including these nine sampling images, when five or more (nine is majority) sampling images for which the equalized evaluation value falls outside of the determination reference range are included. Such determination is referred to as determination based on an anomaly appearance density.

The determination unit 300 may determine that a CD defect is present when the equalized evaluation value of the sampling image deviates from the determination reference range by more than a first threshold value in the determination based on the size of the anomaly. The determination unit 300 may also determine, from among the prescribed number of sampling images, that a CD defect is present when the number or ratio of the sampling images for which the equalized evaluation value falls outside of the determination reference range by more than a second threshold value in the determination based on the anomaly appearance density exceeds a predetermined number or ratio. In this case, the first threshold value may be greater than the second threshold value.

The illumination light L11 is described above as EUV light, but this is merely an example and the illumination light L11 may be light with another wavelength other than EUV light, such as UV light, visible light, or infrared light in accordance with the sample 90. The optical apparatus 1000 is described as being a reflective optical system, but the optical apparatus may include a refractive optical system or a reflective-refractive optical system, as long as the illumination light L11 can be guided in the same manner.

In the above-described embodiments, the image processing apparatus and the inspection apparatus according to the present disclosure are described mainly as a hardware configuration but are not limited thereto. It is also possible to realize the image processing apparatus and the inspection apparatus according to the present disclosure by causing a computer to execute a computer program for performing freely-selected processing. This processing may be realized by causing a computer including at least one processor (for example, microprocessor, CPU, GPU, MPU, or digital signal processor (DSP)) execute a program. To be specific, one or more programs including a set of commands for causing the computer to perform an algorithm related to this transmission signal processing or reception signal processing may be created, and the program may be supplied to the computer.

The computer program can be stored and supplied to the computer, by using various types of non-transitory computer-readable media. The non-transitory computer-readable media include various types of tangible storage media. Examples of the non-transitory computer-readable media include magnetic recording media (for example, flexible disks, magnetic tape, or hard disk drives), magneto-optical recording media (for example, magneto-optical disks), CD read-only memory (ROM), CD-R, CD-R/W, and semiconductor memory (for example, mask ROM, programmable ROM (PROM), erasable PROM (EPROM), flash ROM, random-access memory (RAM)). The program can be supplied to the computer via various types of transitory computer-readable media. Examples of the transitory computer-readable media include electrical signals, optical signals, and electromagnetic waves. The transitory computer-readable media can supply the program to the computers via a wired or wireless communication path, such as an electric wires and optical fiber.

Hereinafter, a configuration example of a computer for realizing the image processing apparatus and the inspection apparatus will be shown. FIG. 10 is a diagram showing the configuration example of the computer for realizing the image processing apparatus and the inspection apparatus. The image processing apparatus and the inspection apparatus can be realized by a computer 9000, such as a dedicated computer or a personal computer (PC). However, the computer need not be a single physical apparatus, but may be a plurality of apparatuses when executing distributed processing. As shown in FIG. 10, the computer 9000 includes, for example, a processor 9001, a read-only memory (ROM) 9002, a random-access memory (RAM) 9003, a storage unit 9004, a communication interface 9005, and a user interface 9006.

The processor 9001, the ROM 9002, the RAM 9003, the storage unit 9004, the communication interface 9005, and the user interface 9006 are communicably connected via a bus 9007. Note that description of OS software or the like for causing the computer to operate is omitted but is introduced in the computer 9000 as appropriate.

The ROM 9002 consists of, for example, a non-volatile semiconductor storage apparatus. The ROM 9002 stores information such as various programs used by the computer 9000.

The storage unit 9004 consists of, for example, various storage apparatuses such as hard disks or solid-state disks. The storage unit 9004 is not limited to the storage apparatuses installed in the computer 9000, but may be external storage apparatuses of the computer 9000. The external storage apparatuses may be a cloud storage or the like connected the computer 9000 via various communication means, for example, a network. The storage unit 9004 stores information such as various programs or data used by the computer 9000.

The RAM 9003 consists of, for example, a volatile semiconductor storage apparatus. In the RAM 9003, information such as programs or data used by the processor 9001 is loaded from one or both of the ROM 9002 and the storage unit 9004 as appropriate.

The processor 9001 may consist of, for example, a central processing unit (CPU). The processor 9001 may include not only a CPU, but also a graphics processing unit (GPU). The GPU is suitable for performing routine processing in parallel, and can also enhance processing speed as compared to the CPU, by applying the GPU to processing in a neural network, for example. The processor 9001 executes various processing based on various programs stored in the ROM 9002 or various programs and data held in the RAM 9003 as appropriate. The processor 9001 may also store data generated by the processing in the RAM 9003, the storage unit 9004, or the like as appropriate.

The communication interface 9005 is an interface that connects the computer 9000 to a communication network, such as the Internet, an intranet, or the like, via various wired or wireless communication means. With this, the computer 9000 can communicate with another apparatus, a system, a sensor, and the like connected to the communication network.

The user interface 9006 includes, for example, a display part, a speech output part, or the like that provides information for a user to recognize via a display apparatus, via speech, or the like. The user interface 9006 includes an input part that allows information to be input to the computer 9000 through a user operation, such as a keyboard, a mouse, or a touch panel. The user interface 9006 may also include equipment such as a sensor that acquires information useful to the user.

Here, the computer 9000 has been described here as one apparatus, but this is merely an example. The computer 9000 may consist of a plurality of apparatuses that are physically separated. Part of the plurality devices may be transportable devices, and others may be stationary apparatuses.

The present disclosure has been described above with reference to the embodiments, but the present disclosure is not limited to the above-described embodiments. From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims. The embodiments can be combined with the other embodiments as appropriate. Hence, the first to third embodiments can be combined as desirable by one of ordinary skill in the art.

Each drawing is merely an example for describing one or more embodiments. Each drawing need not be associated with only one particular embodiment, but may be associated with one or more other embodiments. As those skilled in the art will appreciate, the various features or steps described with reference to any one drawing may be combined with features or steps shown in one or more drawings, for example, to produce an embodiment not explicitly illustrated or described. Not all of the features or steps shown in any one drawing to illustrate an embodiment are necessarily required, and some features or steps may be omitted. The order of the steps shown in any one drawing may be modified as appropriate.

What is claimed is:

1. An image processing apparatus comprising one or more processors configured to execute instructions stored in a memory, the instructions causing the processors to perform:
reading image data obtained by imaging a sample in which a plurality of regions are disposed, each region including a pattern formed based on identical design information;
acquiring, from sampling images at a plurality of sampling points set for each of the plurality of regions, an evaluation value based on pixel luminance for a plurality of sampling images at the same sampling point across the plurality of regions;
acquiring a reference evaluation value corresponding to the evaluation value for the plurality of sampling images at the same sampling point across the plurality of regions; and
acquiring an equalized evaluation value indicating a degree of deviation of the acquired evaluation value from the reference evaluation value, for each of the sampling images of the plurality of regions.

2. The image processing apparatus according to claim 1, wherein the instructions further cause the processors to acquire the evaluation value based on luminance of pixels in a predetermined region set so that an edge portion of the pattern is present for each of the sampling images.

3. The image processing apparatus according to claim 2, wherein the instructions further cause the processors to acquire an average value of the luminance of the pixels in the predetermined region as the evaluation value.

4. The image processing apparatus according to claim 3, wherein the instructions further cause the processors to acquire, as the reference evaluation value for the plurality of sampling images at the same sampling point, an average value of the evaluation value of each of the plurality of sampling images at the same sampling point in the plurality of regions.

5. The image processing apparatus according to claim 3, wherein the instructions further cause the processors to use, as the reference evaluation value, a value obtained from an image generated based on design information of the sample.

6. The image processing apparatus according to claim 4, wherein the instructions further cause the processors to acquire the equalized evaluation value based on a difference between the reference evaluation value and the acquired evaluation value, for each of the sampling images of the plurality of regions.

7. The image processing apparatus according to claim 6, wherein the instructions further cause the processors to acquire, as the equalized evaluation value, a value obtained by dividing the difference between the reference evaluation value and the acquired evaluation value by the reference evaluation value, for each of the sampling images of the plurality of regions.

8. The image processing apparatus according to claim 1, wherein the instructions further cause the processors to create a two-dimensional map indicating a distribution of the equalized evaluation value acquired for each of the sampling images of the plurality of regions and to output the map.

9. The image processing apparatus according to claim 1, wherein the instructions further cause the processors to normalize the luminance of the pixels of the plurality of sampling images at the same sampling point to a predetermined range, and to acquire the evaluation value of each of the plurality of sampling images at the same sampling point after luminance correction.

10. The image processing apparatus according to claim 9, wherein in the image data, luminance of pixels included in the image data is corrected based on a luminance distribution of illumination used to image the sample.

11. The image processing apparatus according to claim 10, wherein in the image data, the luminance of the pixels included in the image data is corrected based on a temporal shift of the luminance distribution of the illumination.

12. The image processing apparatus according to claim 9, wherein the instructions further cause the processors to correct luminance of pixels included in the image data based on a luminance distribution of illumination used to image each sampling point of the sample.

13. The image processing apparatus according to claim 12, wherein the instructions further cause the processors to correct the luminance of the pixels included in the image data based on a temporal shift of the luminance distribution of the illumination.

14. The image processing apparatus according to claim 10, wherein the illumination is critical illumination.

15. An inspection apparatus comprising:
the image processing apparatus according to claim 1; wherein the processors are further configured to detect a defect in a pattern of each of the sampling images of the plurality of regions based on the equalized evaluation value.

16. The inspection apparatus according to claim 15, wherein the processors are further configured to determine that a defect is present in the pattern in a case where the equalized evaluation value for each of the sampling images is outside of a predetermined range.

17. The inspection apparatus according to claim 16, wherein the processors are further configured to determine, from among a predetermined plurality of adjacent sampling images, that a defect is present in the pattern based on the number of the sampling images for which the equalized evaluation value is outside of the predetermined range.

18. The inspection apparatus according to claim 15, wherein
the sample is a photomask, and
the defect includes a critical dimension (CD) defect in the pattern and contamination of the pattern.

19. An inspection apparatus comprising:
the image processing apparatus according to claim 1; wherein the processors are further configured to detect a defect smaller than a width of the pattern based on a difference between the evaluation value of the sampling images and an evaluation value of sampling images in a reference image.

20. An image processing method comprising:
reading image data obtained by imaging a sample in which a plurality of regions are disposed including a pattern formed based on identical design information;
acquiring, from among sampling images at a plurality of sampling points set for each of the plurality of regions, an evaluation value based on luminance of pixels for a plurality of sampling images at the same sampling point across the plurality of regions;
acquiring a reference evaluation value relative to the evaluation value for the plurality of sampling images at the same sampling point across the plurality of regions; and
acquiring an equalized evaluation value indicating a degree of deviation of the acquired evaluation value from the reference evaluation value, for each of the sampling images of the plurality of regions.

21. A non-transitory computer readable medium storing a program for causing a computer to execute:
processing of reading image data obtained by imaging a sample in which a plurality of regions are disposed including a pattern formed based on identical design information;
processing of acquiring, from among sampling images at a plurality of sampling points set for each of the plurality of regions, an evaluation value based on luminance of pixels for a plurality of sampling images at the same sampling point across the plurality of regions;
processing of acquiring a reference evaluation value relative to the evaluation value for the plurality of sampling images at the same sampling point across the plurality of regions; and
processing of acquiring an equalized evaluation value indicating a degree of deviation of the acquired evaluation value from the reference evaluation value, for each of the sampling images of the plurality of regions.
